(19) United States
(12) Patent Application Publication
(10) Pub. No.: US 2023/0261356 A1
(43) Pub. Date: Aug. 17, 2023

(54) Strip-line Structure, Method for Fabricating Strip-line Structure and Electronic Device Thereof

(71) Applicant: Wistron Corporation, New Taipei City (TW)

(72) Inventors: Ming-Yuan Chuang, New Taipei City (TW); Sheng-Hsun Tsai, New Taipei City (TW); Li-Shang Liu, New Taipei City (TW)

(73) Assignee: Wistron Corporation, New Taipei City (TW)

(21) Appl. No.: 17/721,364

(22) Filed: Apr. 15, 2022

(30) Foreign Application Priority Data
Feb. 17, 2022 (TW) 111105759

(51) Int. Cl. H01P 3/08; H01P 11/00; H05K 1/02; H05K 1/11; H04B 15/00

(52) U.S. Cl. CPC H01P 3/08; H01P 11/001; H05K 1/0243; H05K 1/115; H04B 15/00

(57) ABSTRACT

A strip-line structure includes a first ground plane formed on a first layer; a second ground plane formed on a second layer; a first power plane formed on the first layer, wherein the first ground plane and the first power plane are separated by a dielectric material; a stipe line formed on a third layer for signal transmission, wherein the third layer is between the first layer and the second layer; a ground line formed on the third layer, wherein the ground line and the strip line are separated by the dielectric material; a first via for electrically connecting the first ground plane and the second ground plane; and a second via for electrically connecting the ground line and the second ground plane.

### BACKGROUND OF THE INVENTION

### 1. Field of the Invention

The present invention relates to a strip-line structure, a method for fabricating the strip-line structure and an electronic device thereof, and more particularly, to a strip-line structure, a method for fabricating the strip-line structure and an electronic device for forming a reference ground plane under a power plane.

### 2. Description of the Prior Art

In nowadays computer systems, transmitting high-speed signals is a common requirement. However, the high-speed transmission path in the circuit board may be close to the voltage source, which causes the high-speed signals to be affected by the coupled noises. In general, the highest voltage in the computer system is 12 volts (V). When a current transmission path of the voltage source rises from 0 V to 12 V, the amplitude of the voltage disturbance is the largest. Therefore, the noises coupled to the high-speed signal transmission path may be the largest, resulting in reduced reliability of high-speed signal transmission.

Under this circumstance, how to design the relative positions of the current transmission path of the voltage source and its return path to suppress the noises coupled from the current transmission path of the voltage source to the high-speed signal transmission path has become one of the goals in the industry.

### SUMMARY OF THE INVENTION

The present invention is to provide a strip-line structure, a method for fabricating the strip-line structure and an electronic device thereof to solve the above problems.

The present invention provides a strip-line structure, comprising a first ground plane, formed on a first layer; a second ground plane, formed on a second layer; a first power plane, formed on the first layer, wherein the first ground plane and the first power plane are separated by a dielectric material; a strip line, formed on a third layer, utilized for signal transmission, wherein the third layer is between the first layer and the second layer; a ground line, formed on the third layer, wherein the ground line and the strip line are separated by the dielectric material; a first via, electrically connecting the first ground plane and the second ground plane; and a second via, electrically connecting the ground line and the second ground plane.

The present invention provides a method of fabricating a strip-line structure, comprising forming a first ground plane on a first layer; forming a second ground plane on a second layer; forming a first power plane on the first layer, wherein the first ground plane and the first power plane are separated by a dielectric material; forming a strip line utilized for signal transmission on a third layer, wherein the third layer is between the first layer and the second layer; forming a ground line on the third layer, wherein the ground line and the strip line are separated by the dielectric material; forming a first via, for electrically connecting the first ground plane and the second ground plane; and forming a second via, for electrically connecting the ground line and the second ground plane.

The present invention provides an electronic device, comprising a transmission line, made with a strip-line structure; a transmitter; and a receiver, for receiving a signal transmitted by the transmitter via the transmission line; wherein the strip-line structure comprises: a first ground plane, formed on a first layer; a second ground plane, formed on a second layer; a first power plane, formed on the first layer, wherein the first ground plane and the first power plane are separated by a dielectric material; a strip line, formed on a third layer, utilized for signal transmission, wherein the third layer is between the first layer and the second layer; a ground line, formed on the third layer, wherein the ground line and the strip line are separated by the dielectric material; a first via, electrically connecting the first ground plane and the second ground plane; and a second via, electrically connecting the ground line and the second ground plane.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an electronic device according to an embodiment of the present invention.

FIGS. 2A and 2B are schematic diagrams of a side view and a top view of a first strip-line structure according to an embodiment of the present invention.

FIG. 3A is a schematic diagram of a side view of a second strip-line structure according to an embodiment of the present invention.

FIG. 3B is a schematic diagram of a side view of a third strip-line structure according to an embodiment of the present invention.

FIGS. 4A and 4B are simulation diagrams of a first voltage difference and a second voltage difference relative to a first distance and a second distance according to an embodiment of the present invention.

FIG. 5 is a schematic diagram of a side view of a fourth strip-line structure according to an embodiment of the present invention.

FIG. 6 is a schematic diagram of a side view of a fifth strip-line structure according to an embodiment of the present invention.

FIGS. 7A and 7B are simulation diagrams of a fourth voltage difference and a fifth voltage difference relative to a first distance and a second distance according to an embodiment of the present invention.

FIGS. 8A and 8B are simulation diagrams of a fourth voltage difference and a fifth voltage difference relative to the first distance and a strip-line length according to an embodiment of the present invention.

FIG. 9 is a flowchart of a process of method for fabricating a strip-line structure according to the embodiment of the present invention.

### DETAILED DESCRIPTION

Certain terms are used throughout the description and following claims to refer to particular components. As one skilled in the art will appreciate, hardware manufacturers may refer to a component by different names. This document does not intend to distinguish between components that differ in name but not function. In the following description and in the claims, the terms “include” and “comprise” are utilized in an open-ended fashion, and thus should be interpreted to mean “include, but not limited to”. Also, the term “couple” is intended to mean either an indirect or direct electrical connection. Accordingly, if one device is coupled to another device, that connection may be through a direct electrical connection, or through an indirect electrical connection via other devices and connections.

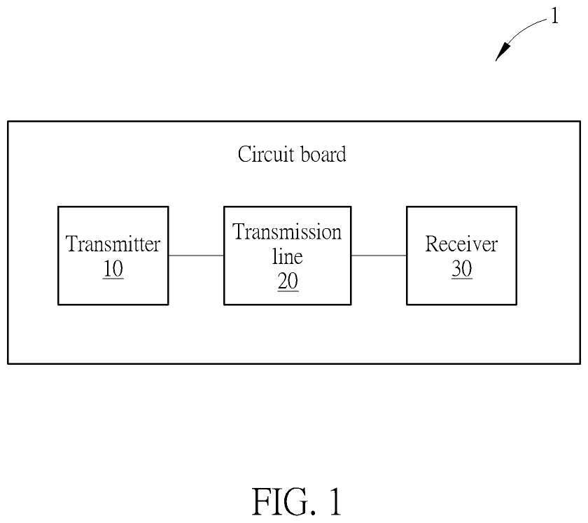

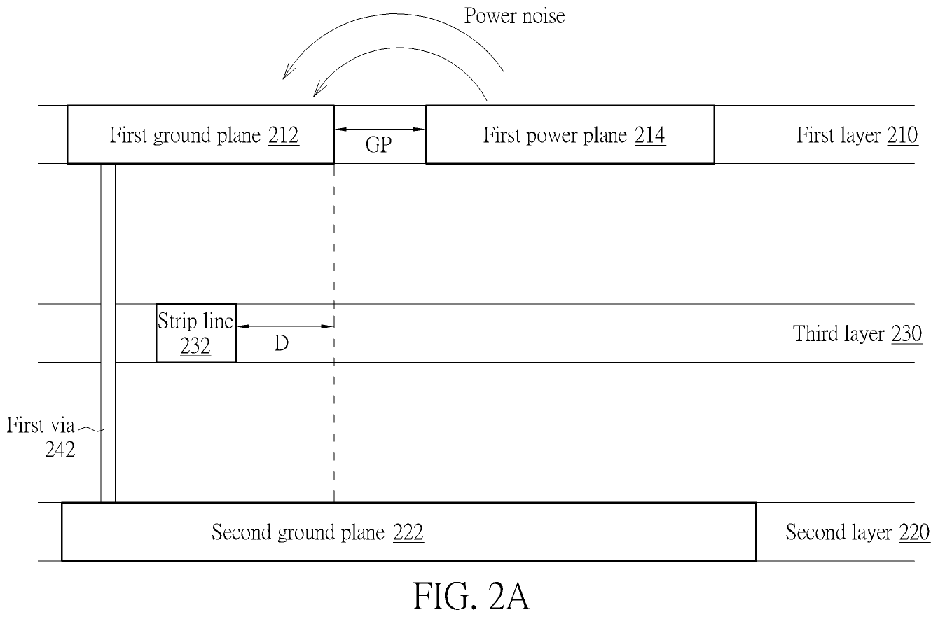

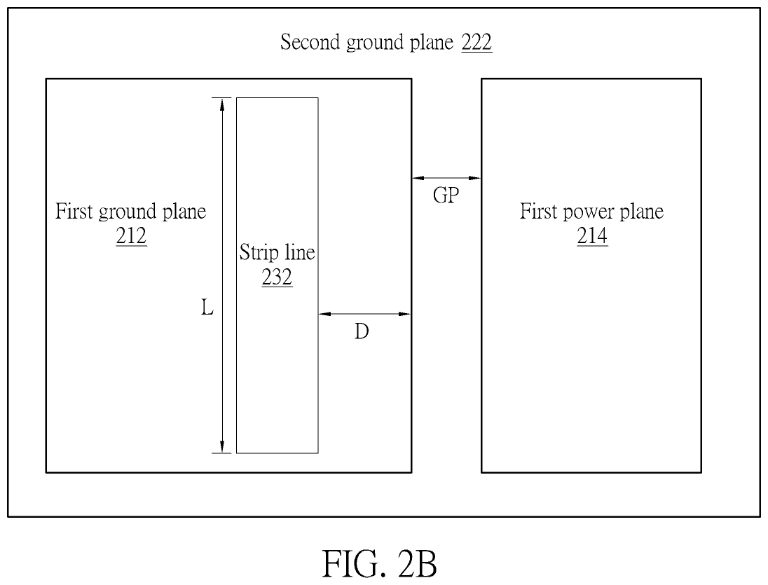

Please refer to FIG. 1. FIG. 1 is a schematic diagram of an electronic device 1 according to an embodiment of the present invention. The electronic device 1 includes a transmitter 10, a transmission line 20 and a receiver 30 arranged on a circuit board. The transmission line 20 is coupled to the transmitter 10 and the receiver 30, and is used to represent a basic element of the electronic device 1 for transmitting signals from the transmitter 10 to the receiver 30 via the transmission line 20, which is not limited thereto. For example, the transmission line 20 may be configured by a first strip-line structure. Please refer to FIGS. 2A and 2B. FIGS. 2A and 2B are schematic diagrams of a side view and a top view of the first strip-line structure according to an embodiment of the present invention. As shown in FIGS. 2A and 2B, the first strip-line structure includes a first ground plane 212 formed on a first layer 210, a first power plane 214 formed on the first layer 210, a second ground plane 222 formed on a second layer 220, a strip line 232 formed on a third layer 230 and a first via 242 for electrically connecting the first ground plane 212 and the second ground plane 222. Furthermore, the strip line 232 is between the first ground plane 212 and the second ground plane 222, and a projected area of the strip line 232 relative to the second layer 220 is smaller than a projected area of the first ground plane 212 relative to the second layer 220. In addition, the first ground plane 212 and the first power plane 214 are separated by a first distance GP, and an edge of the strip line 232 projected to the second layer 220 is separated from an edge of the first ground plane 212 projected to the second layer 220 by a second distance D. The strip line 232 may be formed on the third layer 230 with a strip line length L, and two ends of the strip line 232 are respectively connected to the transmitter 10 and the receiver 30. It should be noted that the first ground plane 212, the first power plane 214, the second ground plane 222, the strip line 232 and the first via 242 may be fabricated by a conductor material and separated from each other by a dielectric material.

In the first strip-line structure, the first power plane 214 may be used as a current transmission path for a voltage source, the first ground plane 212 and the second ground plane 222 may be used as a return path, and the strip line 232 may be used for signal transmission. When the first power plane 214, i.e. the current transmission path, rises from 0 V to 12 V, the amplitude of a voltage disturbance becomes larger. In other words, a power noise coupled from the first power plane 214 to the first ground plane 212 may increase. Therefore, a first voltage difference is generated between the first ground plane 212 and the second ground plane 222, which is related to the power noise coupled from the first power plane 214 to the first ground plane 212. The first voltage difference may be coupled to the strip line 232 between the first ground plane 212 and the second ground plane 222. In other words, the reliability of the signal transmission by the strip line 232 may be reduced. It should be noted that the formula of the common-mode noise of a differential-mode transmission line is well known in the art, which is not repeated hereinafter. Those skilled in the art know that the power noise includes a differential-mode noise and a common-mode noise. However, the differential-mode noise received by the receiver is relatively small compared to the common-mode noise. Therefore, the power noise described below is only based on the common-mode noise. In addition, the common-mode noise of the differential-mode transmission line is equivalent to the common-mode noise of the single-ended signal, so the power noise described below is the common-mode noise of the single-ended signal.

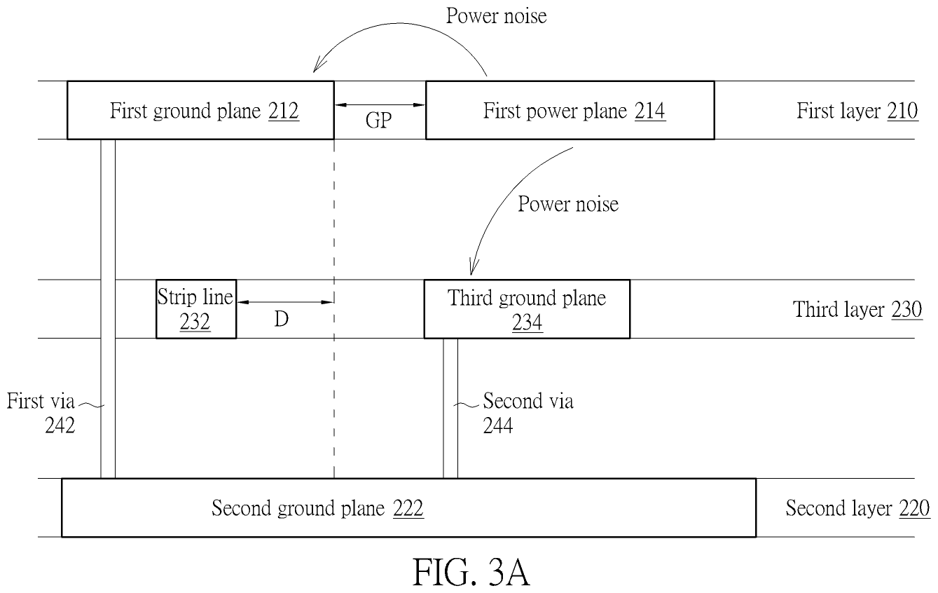

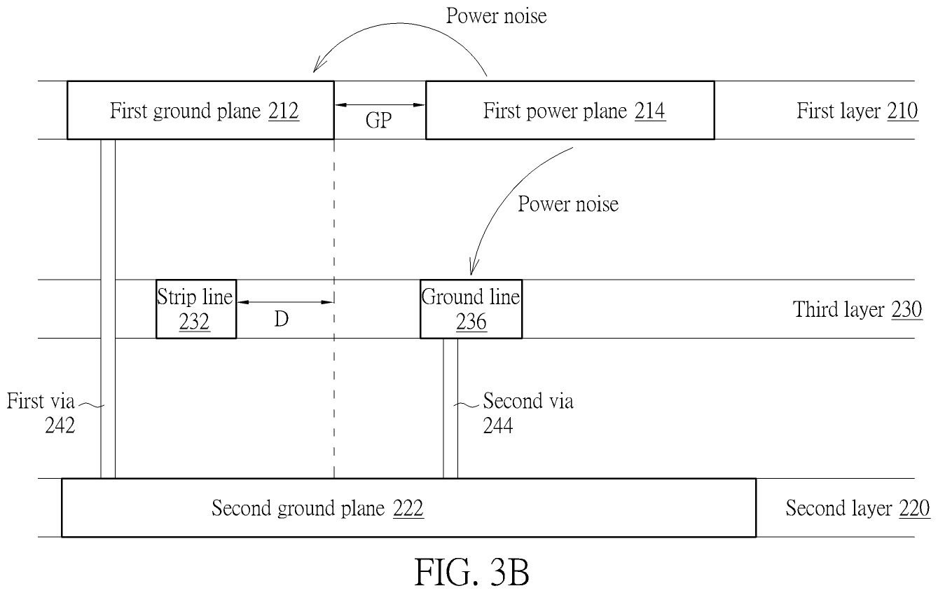

In order to suppress the noise coupled from the current transmission path of the voltage source to the other signal transmission paths, the transmission line 20 of the embodiment of the present invention may be configured in a second strip-line structure. Please refer to FIG. 3A. FIG. 3A is a schematic diagram of a side view of the second strip-line structure according to an embodiment of the present invention. The differences from the first strip-line structure of FIGS. 2A and 2B are that the second strip-line structure further includes a third ground plane 234 formed on the third layer 230 and a second via 244 utilized for electrically connecting the second ground plane 222 and the third ground plane 234. Specifically, a projected area of the third ground plane 234 relative to the second layer 220 is smaller than a projected area of the first power plane 214 relative to the second layer 220. When the first power plane 214, i.e. the current transmission path, rises from 0V to 12V, the amplitude of a voltage disturbance becomes larger, and the power noise is coupled from the first power plane 214 to the first ground plane 212 and the third ground plane 234. Therefore, a second voltage difference is generated between the first ground plane 212 and the second ground plane 222, which is related to the power noise coupled from the first power plane 214 to the first ground plane 212. The second voltage difference may be coupled to the strip line 232 between the first ground plane 212 and the second ground plane 222, so that the reliability of the signal transmission of the strip line 232 is reduced. It should be noted that in the first strip-line structure, the power noise is only coupled from the first power plane 214 to the first ground plane 212. In the second strip-line structure, the power noise is coupled from the first power plane 214 to the first ground plane 212 and the third ground plane 234. For example, FIG. 2A illustrates that the power noise is coupled from the first power plane 214 to the first ground plane 212, and an intensity of the power noise is indicated by two arrows. In comparison, FIG. 3A illustrates that the power noise are coupled from the first power plane 214 to the first ground plane 212 and the third ground plane 234, and are respectively indicated by one arrow. Therefore, the power noise coupled from the second strip-line structure to the first ground plane 212 is smaller than the power noise of the first strip-line structure coupled to the first ground plane 212. Specifically, the second voltage difference generated between the first ground plane 212 and the second ground plane 222 of the second strip-line structure is smaller than the first voltage difference generated between the first ground plane 212 and the second ground plane 222 of the first strip-line structure, and the influence of the second voltage difference coupled to the strip line 232 is smaller than the influence of the first voltage difference coupled to the strip line 232. In other words, the reliability of the signal transmission of the strip line 232 configured in the second strip-line structure may be better than the reliability of the signal transmission of the strip line 232 configured in the first strip-line structure.

In another embodiment, the transmission line 20 may be configured in a third strip-line structure. Please refer to FIG. 3B. FIG. 3B is a schematic diagram of a side view of the third strip-line structure according to an embodiment of the present invention. The differences from the first strip-line structure of FIGS. 2A and 2B are that the third strip-line structure further includes a ground line 236 formed on the third layer 230 and a second via 244 utilized for electrically connecting the second ground plane 222 and the third ground plane 234. Specifically, a projected area of the ground line 236 relative to the second layer 220 is smaller than a projected area of the first power plane 214 relative to the second layer 220, and is smaller than a projected area of the third ground plane 234 of the strip-line structure relative to the second layer 220. Similarly, the power noise is coupled from the first power plane 214 to the first ground plane 212 and the ground line 236, and a third voltage difference is generated between the first ground plane 212 and the second ground plane 222 relative to the power noise coupled from the first power plane 214 to the first ground plane 212. In comparison, the third voltage difference is also smaller than the first voltage difference, and the reliability of the signal transmission of the strip line 232 configured in the third strip-line structure is better than the reliability of the signal transmission of the strip line 232 configured in the first strip line.

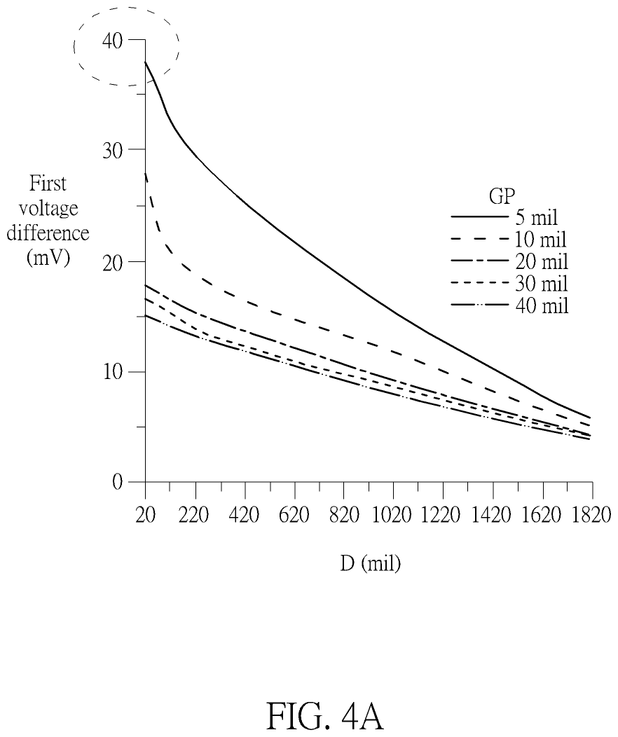

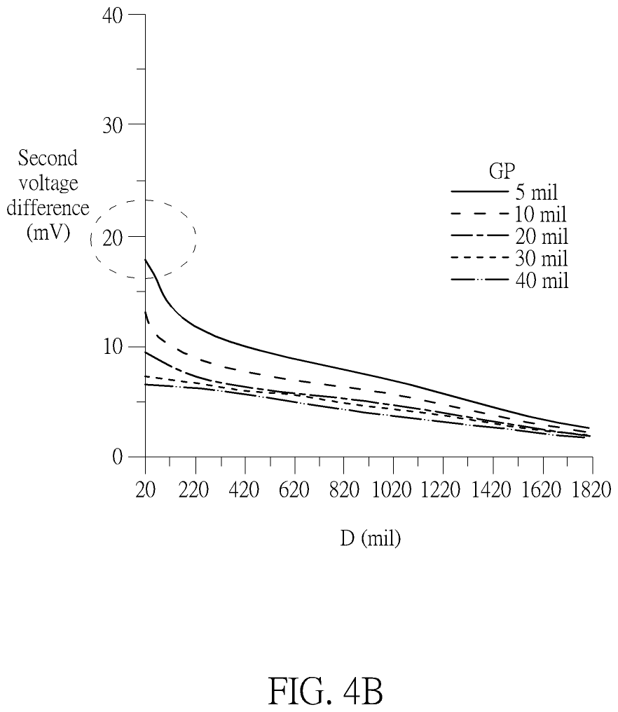

As mentioned above, in the first, second, third strip-line structures, the first distance GP represents the distance between the first ground plane 212 and the first power plane 214, the second distance D represents the distance between edges of the strip line 232 and the first ground plane 212 projected to the second layer 220. Please refer to FIGS. 4A and 4B. FIGS. 4A and 4B are simulation diagrams of the first voltage difference and the second voltage difference relative to the first distance GP and the second distance D according to an embodiment of the present invention. When the first distance GP is 5 mil and the second distance D is 20 mil, the first voltage difference is 38 mV, and the second voltage difference is 17 mV. The second voltage difference is obviously smaller than the first voltage difference. In other words, the reliability of the signal transmission of the strip line 232 configured in the second strip-line structure is better than the reliability of the signal transmission of the strip line 232 configured in the first strip-line structure. Similarly, the reliability of the signal transmission of the strip line 232 configured in the third strip-line structure is better than the reliability of the signal transmission of the strip line 232 configured in the first strip-line structure.

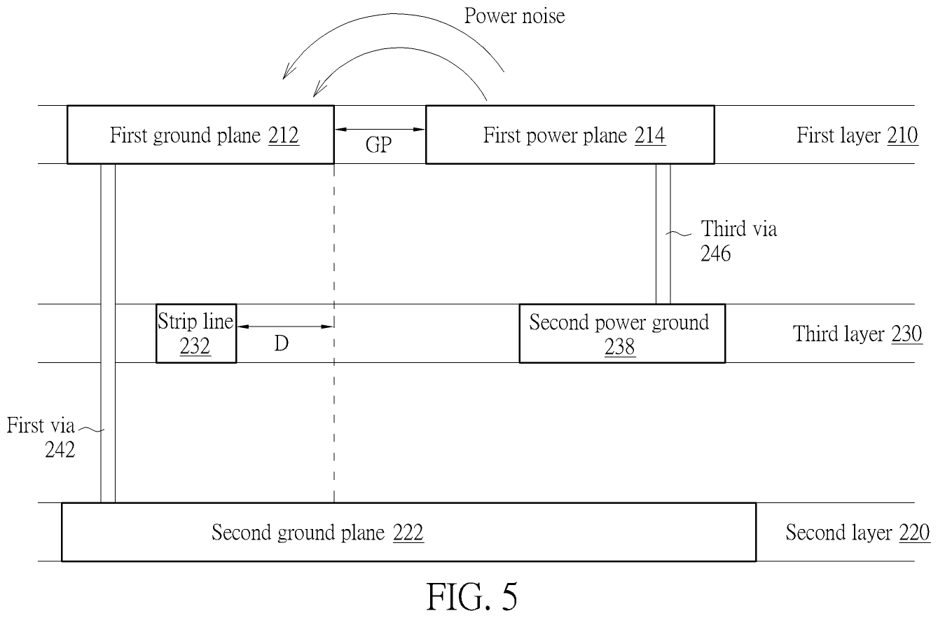

On the other hand, when the electronic device 1 has a design requirement of high current, the transmission line 20 with only one power plane; for example, the first power plane 214 is no longer sufficient. In an embodiment, the transmission line 20 may be configured in a fourth strip-line structure. Please refer to FIG. 5. FIG. 5 is a schematic diagram of a side view of the fourth strip-line structure according to an embodiment of the present invention. The differences from the first strip-line structure of FIGS. 2A and 2B are that the fourth strip-line structure further includes a second power plane 238 formed on the third layer 230 and a third via 246 for electrically connecting the first power plane 214 and the second power plane 238, wherein the second power plane 238 is between the first power plane 214 and the second ground plane 222. When the first power plane 214, i.e. the current transmission path, rises from 0 V to 12 V, the amplitude of a voltage disturbance becomes larger, and the power noise is coupled from the first power plane 214 to the first ground plane 212. Therefore, a fourth voltage difference is generated between the first ground plane 212 and the second ground plane 222 relative to the power noise coupled from the first power plane 214 to the first ground plane 212. The fourth voltage difference may be coupled to the strip line 232 between the first ground plane 212 and the second ground plane 222. In other words, the reliability of the signal transmission of the strip line 232 may be reduced.

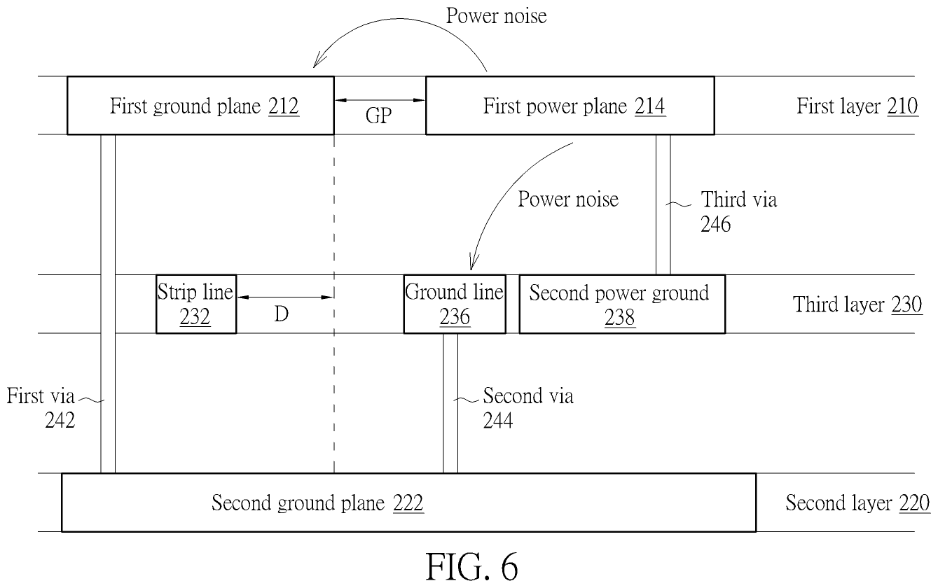

In another embodiment, the transmission line 20 may be configured in a fifth strip-line structure. Please refer to FIG. 6. FIG. 6 is a schematic diagram of a side view of the fifth strip-line structure according to an embodiment of the present invention. The differences from the fourth the strip-line structure of FIG. 5 are that the fifth strip-line structure further includes the ground line 236 (same as the third strip-line structure) formed on the third layer 230 and the second via 244 for electrically connecting the second ground plane 222 and the third ground plane 234. Specifically, a projected area of the second power plane 238 relative to the second layer 220 is smaller than a projected area of the first power plane 214 relative to the second layer 220. Therefore, the ground line 236 may be formed between the strip line 232 and the second power plane 238 and between the first power plane 214 and the second ground plane 222. When the first power plane 214, i.e. the current transmission path, rises from 0 V to 12 V, the amplitude of the voltage disturbance becomes larger, and the power noise is coupled from the first power plane 214 to the first ground plane 212 and the ground line 236. Therefore, a fifth voltage difference is generated between the first ground plane 212 and the second ground plane 222 relative to the power noise coupled from the first power plane 214 to the first ground plane 212. The fifth voltage difference may be coupled to the strip line 232 between the first ground plane 212 and the second ground plane 222, so that the reliability of the signal transmission of the strip line 232 may be reduced. It should be noted that in the fourth strip-line structure as shown in FIG. 5, the power noise is only coupled from the first power plane 214 to the first ground plane 212. In the fifth strip-line structure, the power noise is coupled from the first power plane 214 to the first ground plane 212 and the third ground plane 234. Therefore, the fifth voltage difference generated between the first ground plane 212 and the second ground plane 222 of the fifth strip-line structure is smaller than the fourth voltage difference generated between the first ground plane 212 and the second ground plane 222 of the fourth strip-line structure, and the influence of the fifth voltage difference coupled to the strip line 232 is smaller than the influence of the fourth voltage difference coupled to the strip line 232. In other words, the reliability of the signal transmission of the strip line 232 configured in the fifth strip-line structure is better than the reliability of the signal transmission of the strip line 232 configured in the fourth strip-line structure.

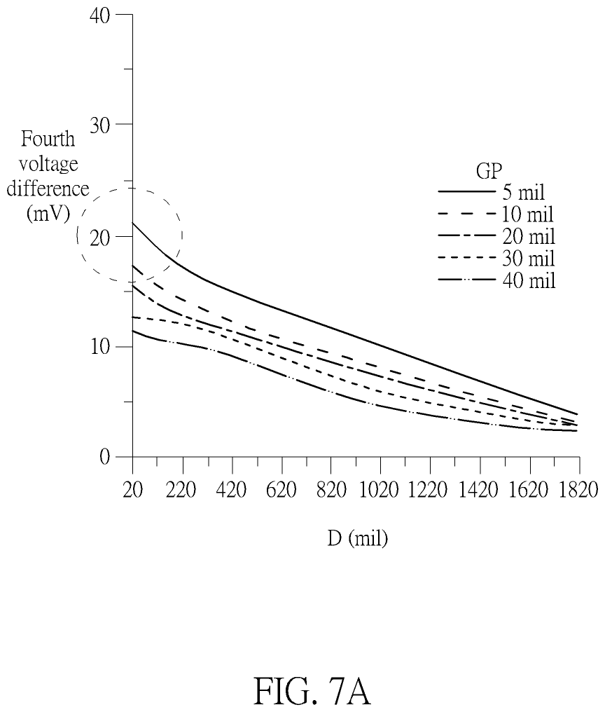

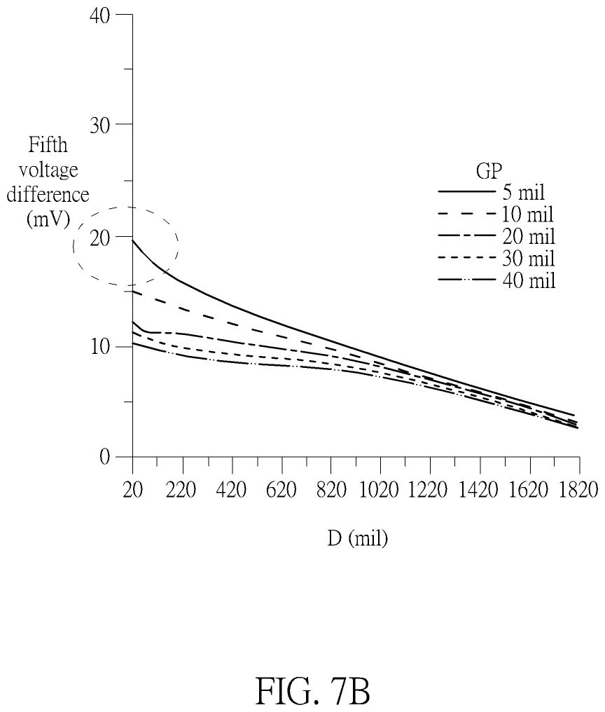

Please refer to FIGS. 7A and 7B. FIGS. 7A and 7B are simulation diagrams of the fourth voltage difference and a fifth voltage difference relative to the first distance GP and the second distance D according to an embodiment of the present invention. When the first distance GP is 5 mil and the second distance D is 20 mil, the fourth voltage difference is 22 mV, and the fifth voltage difference is 19 mV. Therefore, the fifth voltage difference is smaller than the fourth voltage difference. In other words, the reliability of the signal transmission of the strip line 232 configured in the fifth strip-line structure is better than the reliability of the signal transmission of the strip line 232 configured in the fourth strip-line structure.

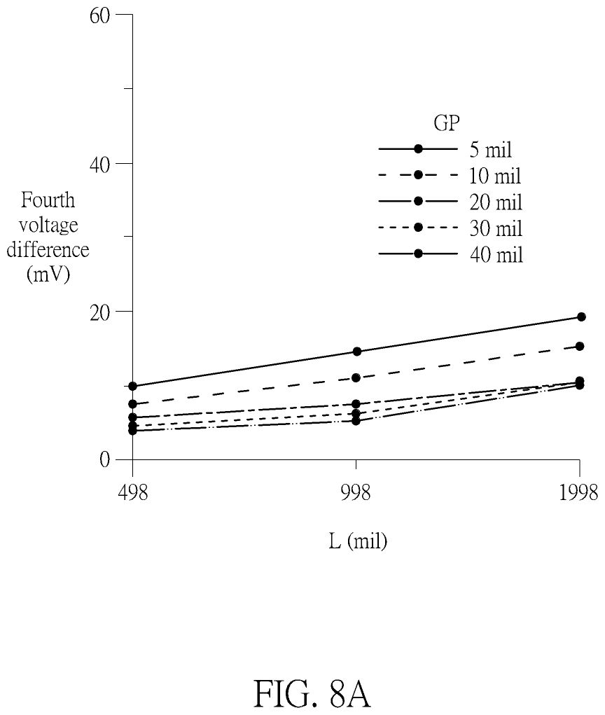

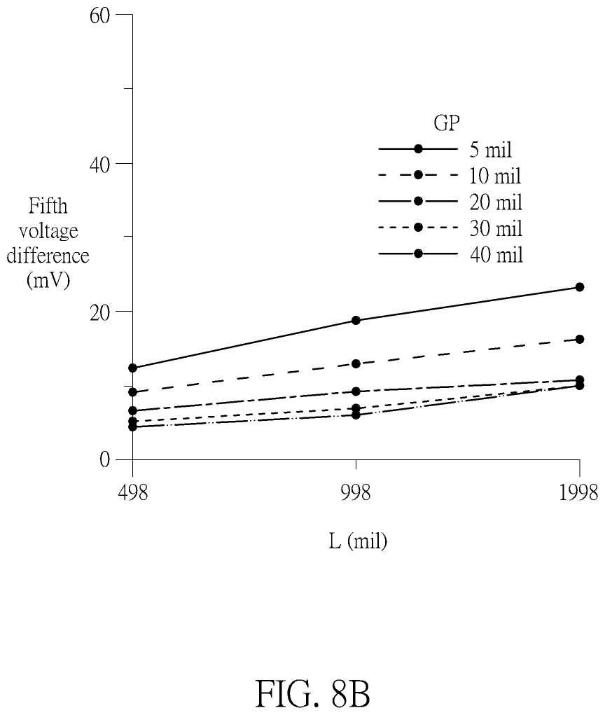

On the other hand, as mentioned above, the strip line 232 may be formed on the third layer 230 with the strip line length L. Please refer to FIGS. 8A and 8B. FIGS. 8A and 8B are simulation diagrams of a fourth voltage difference and a fifth voltage difference relative to the first distance and a strip-line length according to an embodiment of the present invention. When the strip line length L is increased and the first distance GP is fixed, both the fourth voltage difference and the fifth voltage difference become larger. It should be noted that when the first distance GP is 5 mil and the strip line length L is 498 mil, the difference between the fourth voltage difference and the fifth voltage difference is only 1 mV. When the first distance GP is 5 mil and the strip line length L is 1998 mil, the difference between the fourth voltage difference and fifth voltage difference is 4 mV. In other words, the longer the strip line length L is, the greater the improvement between the reliability of the signal transmission of the strip line 232 configured in the fifth strip-line structure and the reliability of the signal transmission of the strip line 232 configured in the fourth strip-line structure.

It should be noted that those skilled in the art may appropriately design the strip-line structure of the transmission line. For example, the strip line length L, the first distance GP and the second distance D may be adjusted according to the requirements of users or devices, but are not limited thereto.

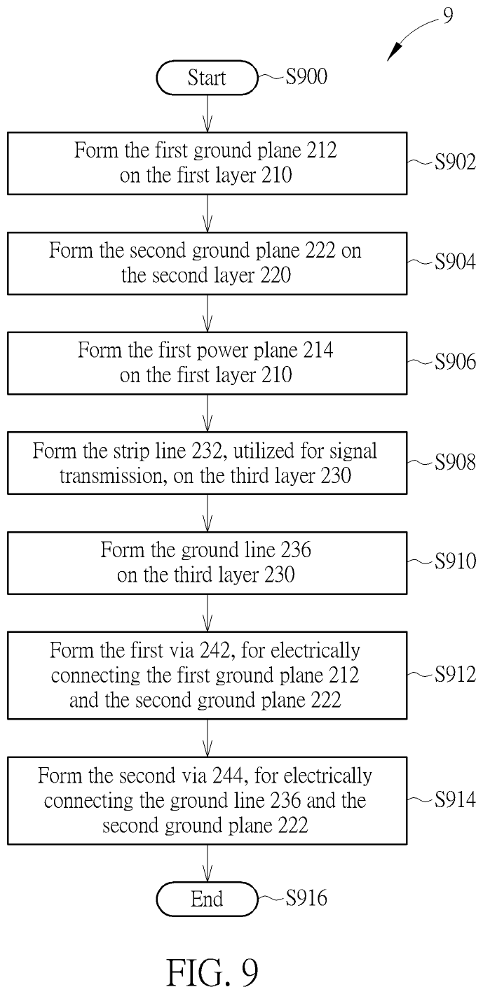

The above-mentioned fabricating method of the strip-line structure according to the embodiments of the present invention may be summarized as a process 9, as shown in FIG. 9. The process 9 includes the following steps:

Step S900: Start.

Step S902: Form the first ground plane 212 on the first layer 210.

Step S904: Form the second ground plane 222 on the second layer 220.

Step S906: Form the first power plane 214 on the first layer 210.

Step S908: Form the strip line 232, utilized for signal transmission, on the third layer 230.

Step S910: Form the ground line 236 on the third layer 230.

Step S912: Form the first via 242, for electrically connecting the first ground plane 212 and the second ground plane 222.

Step S914: Form the second via 244, for electrically connecting the ground line 236 and the second ground plane 222.

Step S916: End.

According to the process 9, the transmission line 20 may be configured in the strip-line structure for transmitting the signal from the transmitter 10 to the receiver 30 via the transmission line 20. For the detailed fabricating method and differences of the strip-line structures, please refer to the descriptions in the above paragraphs, which will not be repeated herein.

In summary, in the present invention, a reference ground plane (i.e., the third ground plane or the ground line) is formed under the first power plane of the strip-line structure configured in a single power plane, and a guard plane (i.e., the ground line) is formed between the second power plane and the strip line of the strip-line structure configured in multiple power planes. Compared with conventional strip-line structure, the reliability of high speed signal transmission of the present invention may be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A strip-line structure, comprising:
a first ground plane, formed on a first layer;
a second ground plane, formed on a second layer;
a first power plane, formed on the first layer, wherein the first ground plane and the first power plane are separated by a dielectric material;
a strip line, formed on a third layer, utilized for signal transmission, wherein the third layer is between the first layer and the second layer;
a ground line, formed on the third layer, wherein the ground line and the strip line are separated by the dielectric material;
a first via, electrically connecting the first ground plane and the second ground plane; and
a second via, electrically connecting the ground line and the second ground plane.

2. The strip-line structure of claim 1, wherein a projected area of the ground line relative to the second layer is smaller than a projected area of the first power plane relative to the second layer.

3. The strip-line structure of claim 1, wherein a projected area of the strip line relative to the second layer is smaller than a projected area of the first ground plane relative to the second layer.

4. The strip-line structure of claim 1, further comprising:
a second power plane, formed on the third layer, wherein the ground line and the second power plane are separated by the dielectric material; and
a third via, electrically connecting the first power plane and the second power plane.

5. The strip-line structure of claim 4, wherein a projected area of the second power plane relative to the second layer is smaller than a projected area of the first power plane relative to the second layer.

6. The strip-line structure of claim 4, wherein the ground line is between the strip line and the second power plane on the third layer.

7. A method of fabricating a strip-line structure, comprising:
forming a first ground plane on a first layer;
forming a second ground plane on a second layer;
forming a first power plane on the first layer, wherein the first ground plane and the first power plane are separated by a dielectric material;
forming a strip line utilized for signal transmission on a third layer, wherein the third layer is between the first layer and the second layer;
forming a ground line on the third layer, wherein the ground line and the strip line are separated by the dielectric material;
forming a first via, for electrically connecting the first ground plane and the second ground plane; and
forming a second via, for electrically connecting the ground line and the second ground plane.

8. The method of claim 7, wherein a projected area of the ground line relative to the second layer is smaller than a projected area of the first power plane relative to the second layer.

9. The method of claim 7, wherein a projected area of the strip line relative to the second layer is smaller than a projected area of the first ground plane relative to the second layer.

10. The method of claim 7, further comprising:
forming a second power plane on the third layer, wherein the ground line and the second power plane are separated by the dielectric material; and
forming a third via, for electrically connecting the first power plane and the second power plane.

11. The method of claim 10, wherein a projected area of the second power plane relative to the second layer is smaller than a projected area of the first power plane relative to the second layer.

12. The method of claim 10, wherein the ground line is between the strip line and the second power plane on the third layer.

13. An electronic device, comprising:
a transmission line, fabricated with a strip-line structure;
a transmitter; and
a receiver, for receiving a signal transmitted by the transmitter via the transmission line;
wherein the strip-line structure comprises:
a first ground plane, formed on a first layer;
a second ground plane, formed on a second layer;
a first power plane, formed on the first layer, wherein the first ground plane and the first power plane are separated by a dielectric material;
a strip line, formed on a third layer, utilized for signal transmission, wherein the third layer is between the first layer and the second layer;
a ground line, formed on the third layer, wherein the ground line and the strip line are separated by the dielectric material;
a first via, electrically connecting the first ground plane and the second ground plane; and
a second via, electrically connecting the ground line and the second ground plane.

14. The electronic device of claim 13, wherein a projected area of the ground line relative to the second layer is smaller than a projected area of the first power plane relative to the second layer.

15. The electronic device of claim 13, wherein a projected area of the strip line relative to the second layer is smaller than a projected area of the first ground plane relative to the second layer.

16. The electronic device of claim 13, further comprising:
a second power plane, formed on the third layer, wherein the ground line and the second power plane are separated by the dielectric material; and
a third via, electrically connecting the first power plane and the second power plane.

17. The electronic device of claim 16, wherein a projected area of the second power plane relative to the second layer is smaller than a projected area of the first power plane relative to the second layer.

18. The electronic device of claim 16, wherein the ground line is between the strip line and the second power plane on the third layer.
